(19) United States
(12) Patent Application Publication
(10) Pub. No.: US 2018/0080124 A1
(43) Pub. Date: Mar. 22, 2018

(54) METHODS AND SYSTEMS FOR THERMAL ALE AND ALD

(71) Applicant: APPLIED MATERIALS, INC., Santa Clara, CA (US)

(72) Inventors: Geetika Bajaj, New Delhi (IN); Ranga Rao Arnepalli, Krishna (IN); Prerna Sonthalia Goradia, Mumbai (IN); Robert Jan Visser, Menlo Park, CA (US)

(21) Appl. No.: 15/269,405

(22) Filed: Sep. 19, 2016

(51) Int. Cl. C23C 16/455; C23C 16/52; C23F 1/08

(52) U.S. Cl. CPC C23C 16/45565; C23C 16/52; C23C 16/45544; C23C 16/45527; C23F 1/08

(57) ABSTRACT

Systems and methods for selectively etching and depositing material on the surface of a substrate are described. Systems for atomic layer etching (ALE) and atomic layer deposition (ALD) are described which enable alternating exposure to a first precursor and then a second precursor. The substrate processing region is configured to process large surface area substrate (e.g. 300 mm wafers) without requiring direct line-of-sight pathways between the gas inlet into the substrate processing chamber and all portions of the substrate. No plasma excites either of the two precursors either remotely or locally in embodiments. A quartz crystal microbalance is placed close to the substrate pedestal to quantify deposition and etching rates. Only thermal energy from the substrate is used to get the chemical reactions to proceed according to embodiments.

### FIELD

The embodiments described herein relate to atomic layer deposition and atomic layer etching.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers or thinning lateral dimensions of features already present on the surface. Often it is desirable to have an etch process which etches one material faster than another helping e.g. a pattern transfer process proceed. Such an etch process is said to be selective of the first material. As a result of the diversity of materials, circuits and processes, etch processes have been developed that selectively remove one or more of a broad range of materials.

Dry etch processes are often desirable for selectively removing material from semiconductor substrates. The desirability stems from the ability to gently remove material from miniature structures with minimal physical disturbance. Dry etch processes also allow the etch rate to be abruptly stopped by removing the gas phase reagents. Some dry-etch processes involve the exposure of a substrate to remote plasma by-products formed from one or more precursors. Many dry etch processes have recently been developed to selectively remove a variety of dielectrics relative to one another. However, relatively few dry-etch processes have been developed to selectively remove material with atomic layer precision. Methods and systems are needed to etch layers with atomic layer precision. Current and upcoming semiconductor manufacturing require mass production of features having 10 nm critical dimension (CD) and may require CD variation of 0.5 nm or less. The use of ultra-thin gate dielectrics, ultra-thin channels, and overall decreasing film thicknesses in combination with more stringent demands on surface property control in field effect transistors, preventing materials damage, requires control over etching directionality and material selectivity.

### SUMMARY

Systems and methods for selectively etching and depositing material on surface of a substrate are described. Systems for atomic layer etching (ALE) and atomic layer deposition (ALD) are described which enable alternating exposure to a first precursor and then a second precursor. The substrate processing region is configured to process large surface area substrate (e.g. 300 mm wafers) without requiring direct line-of-sight pathways between the gas inlet into the substrate processing chamber and all portions of the substrate. In the past, atomic layer etching systems and methods have relied on ion beams or energetic neutral beam bombardment to make the necessary half reactions proceed. Methods of using the systems are also described. No plasma excites either of the two precursors either remotely or locally in embodiments. The substrate may be heated to a relatively high temperature to accelerate the chemical half reactions. A quartz crystal microbalance is disposed close to the substrate pedestal to quantify deposition and etching rates. The use of quartz crystal microbalance is enabled by the system and chemistry which lacks the line-of-sight configuration and requirement. Only thermal energy from the substrate is used to get the chemical reactions to proceed according to embodiments.

Embodiments disclosed herein include substrate processing systems. The systems include a substrate processing chamber containing a substrate processing region. The systems further include a first precursor source. The systems further include a first upstream source valve fluidly coupled to the first precursor source. The systems further include a first dump valve fluidly coupled to the upstream source valve. The systems further include a first pump fluidly coupled to the dump valve. The systems further include a first downstream source valve fluidly coupled to the first upstream source valve. The systems further include a first chamber entry valve fluidly coupled to the first downstream source valve and to the substrate processing chamber at a first entry point. The systems further include a second precursor source. The systems further include a second upstream source valve fluidly coupled to the second precursor source. The systems further include a second dump valve fluidly coupled to the upstream source valve. The systems further include a second pump fluidly coupled to the dump valve. The systems further include a second downstream source valve fluidly coupled to the second upstream source valve. The systems further include a second chamber entry valve fluidly coupled to the second downstream source valve and to the substrate processing chamber at a second entry point. The systems further include a precursor distributor disposed within the substrate processing chamber. The systems further include a substrate pedestal configured to support a substrate. There are portions of the substrate which are physically shielded by the precursor distributor from a direct line-of-sight path from the first entry point and the second entry point.

The first precursor source may be a bubbler. The first entry point may be the same as the second entry point. The systems may further include a first supply filter fluidly coupled between the first upstream source valve and the first downstream source valve. The systems may further include a first purge gas source and a first purge gas valve fluidly coupled between the first purge gas source and the first chamber entry valve. The systems may further include a first mass flow controller fluidly coupled between the first purge gas valve and the first chamber entry valve. The precursor distributor may be a showerhead separating a remote region from the substrate processing region. The precursor distributor may be a baffle. The systems may further include a quartz crystal microbalance placed within the substrate processing region. The quartz crystal microbalance is positioned between the substrate and the first entry point. The quartz crystal microbalance is placed next to the substrate such that the quartz crystal microbalance and the substrate are coplanar.

Embodiments disclosed herein include methods of depositing material onto a surface of a patterned substrate in a substrate processing region of a substrate processing chamber. The methods include at least four sequential steps (defined as a “deposition cycle”) including (i) exposing the patterned substrate to a first precursor into the substrate processing region through a first entry point on the substrate processing chamber, (ii) removing process effluents including unreacted first precursor from the substrate processing region, (iii) exposing the patterned substrate to a second precursor into the substrate processing region through a second entry point on the substrate processing chamber, and (iv) removing process effluents including unreacted second precursor from the substrate processing region. No direct line-of-sight path exists between a portion of the substrate and the entry point of the first precursor into the substrate processing chamber. The deposition cycle may be repeated an integral number of times and each deposition cycle may deposit a monolayer of material onto the surface of the patterned substrate. The patterned substrate may include patterned features which shield portions of the surface of the patterned substrate from a direct line-of-sight path to the second entry point.

Embodiments disclosed herein include methods etching material from a surface of a patterned substrate in a substrate processing region of a substrate processing chamber. The methods include at least four sequential steps (an etch cycle) including (i) exposing the patterned substrate to a first precursor into the substrate processing region through a first entry point on the substrate processing chamber, (ii) removing process effluents including unreacted first precursor from the substrate processing region, (iii) exposing the patterned substrate to a second precursor into the substrate processing region through a second entry point on the substrate processing chamber, and (iv) removing process effluents including unreacted second precursor from the substrate processing region. No direct line-of-sight path exists between a portion of the substrate and the entry point of the first precursor into the substrate processing chamber. The etch cycle may be repeated an integral number of times and each etch cycle may remove a monolayer of material from the surface of the patterned substrate. The patterned substrate may include patterned features which shield portions of the surface of the patterned substrate from a direct line-of-sight path to the first entry point.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### DESCRIPTION OF THE DRAWINGS

A further understanding of the nature and advantages of the disclosed embodiments may be realized by reference to the remaining portions of the specification and the drawings.

FIG. 1A shows a system for atomic layer etching or deposition according to embodiments.

FIG. 1B shows a system for atomic layer etching or deposition according to embodiments.

FIG. 1C shows a system for atomic layer etching or deposition according to embodiments.

FIG. 1D shows a system for atomic layer etching or deposition according to embodiments.

FIG. 2 is a flow chart of an atomic layer deposition process according to embodiments.

FIG. 3 is a flow chart of an atomic layer etch process according to embodiments.

FIG. 4 shows a top view of an exemplary substrate processing system according to embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Systems and methods for selectively etching and depositing material on surface of a substrate are described. Systems for atomic layer etching (ALE) and atomic layer deposition (ALD) are described which enable alternating exposure to a first precursor and then a second precursor. The substrate processing region is configured to process large surface area substrate (e.g. 300 mm wafers) without requiring direct line-of-sight pathways between the gas inlet into the substrate processing chamber and all portions of the substrate. In the past, atomic layer etching systems and methods have relied on ion beams or energetic neutral beam bombardment to make the necessary half reactions proceed. Methods of using the systems are also described. No plasma excites either of the two precursors either remotely or locally in embodiments. The substrate may be heated to a relatively high temperature to accelerate the chemical half reactions. A quartz crystal microbalance is disposed close to the substrate pedestal to quantify deposition and etching rates. The use of quartz crystal microbalance is enabled by the system and chemistry which lacks the line-of-sight configuration and requirement. Only thermal energy from the substrate is used to get the chemical reactions to proceed according to embodiments.

Both ALD and ALE processes may involve self-limiting chemical reactions between gaseous precursor molecules and the surface of a solid substrate. In ALD (atomic layer deposition), two half reaction lead to deposition of a monolayer. In ALE (atomic layer etching), one atomic layer of material is removed. In ALD, a first reactant will get adsorbed to the surface and any unreacted or leftover precursors are removed from the substrate processing region by displacement using a vacuum pump with optional assistance of a purge gas. A second reactant is added which reacts with adsorbed first reactant to create one monolayer of material on the surface. An inert carrier gas can be used to transport precursors to the substrate processing chamber and into the substrate processing region. ALD of different films can be executed on this apparatus by choosing different chemistries and process conditions.

ALE processes may rely on the ion or energetic neutral noble atom bombardment to remove the surface complexes enabling etching. ALE based on ion or neutral noble atom bombardment requires line-of-sight to the substrate which makes this approach limited to the relatively small surface areas that are subjected to ion or neutral noble atom bombardment. Also, ALE based on ion or neutral noble atom bombardment can potentially affect the underlying substrate. Thermal ALE is a chemistry-oriented approach described herein which employs self-limiting reaction with thermal energy used to desorb etch products. Thermal ALE approach avoids damage to the underlying substrate resulting from high energy ions or energetic neutrals. The thermal ALE approach can be used to etch high surface area and high aspect ratio structures which ordinarily would shield ion beams or molecular beams. Additionally, thermal ALE may use use a novel substrate processing chamber due to the removal of a reliance on energetic plasma or remote plasma to remove the etch products.

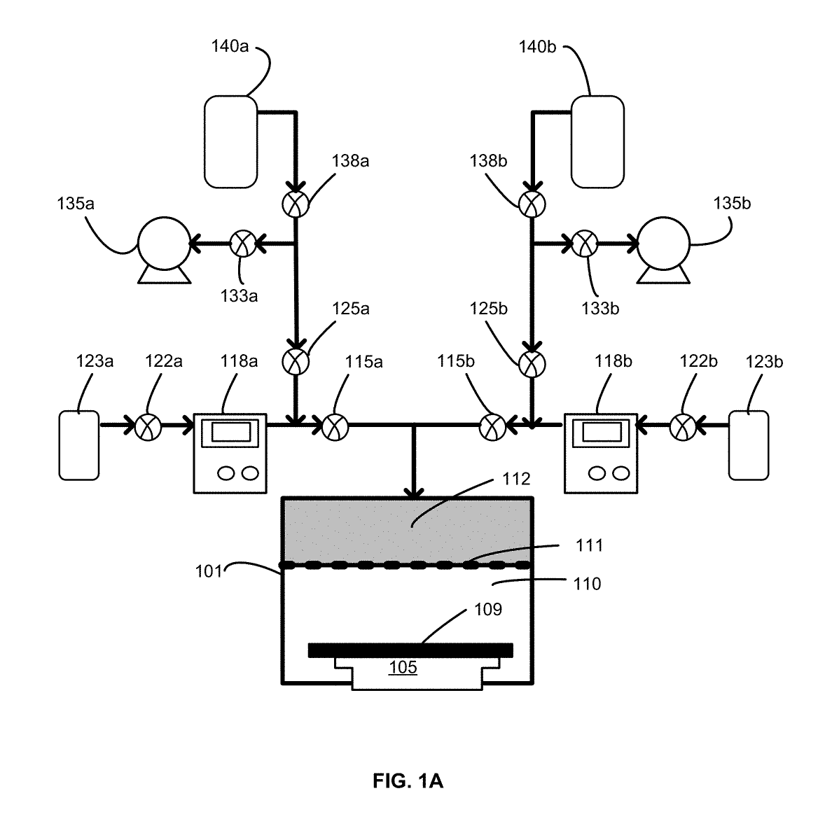

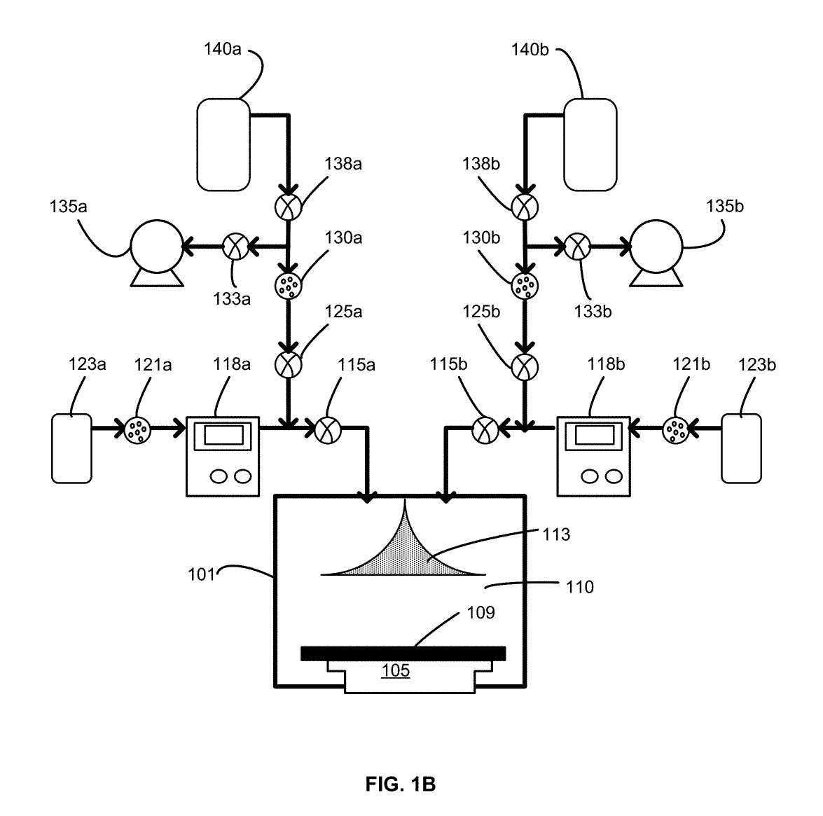

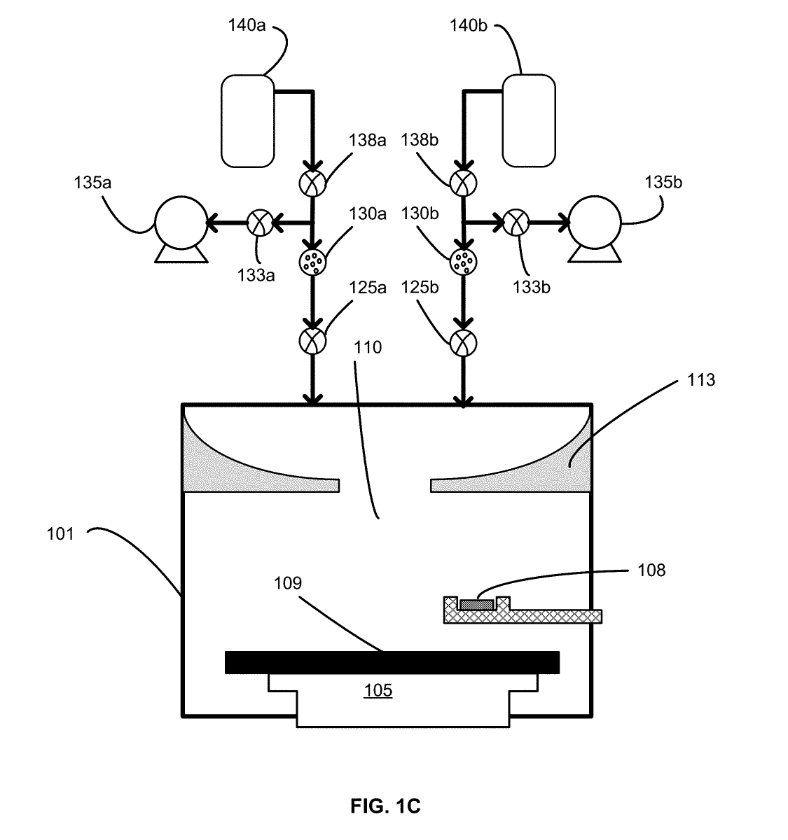

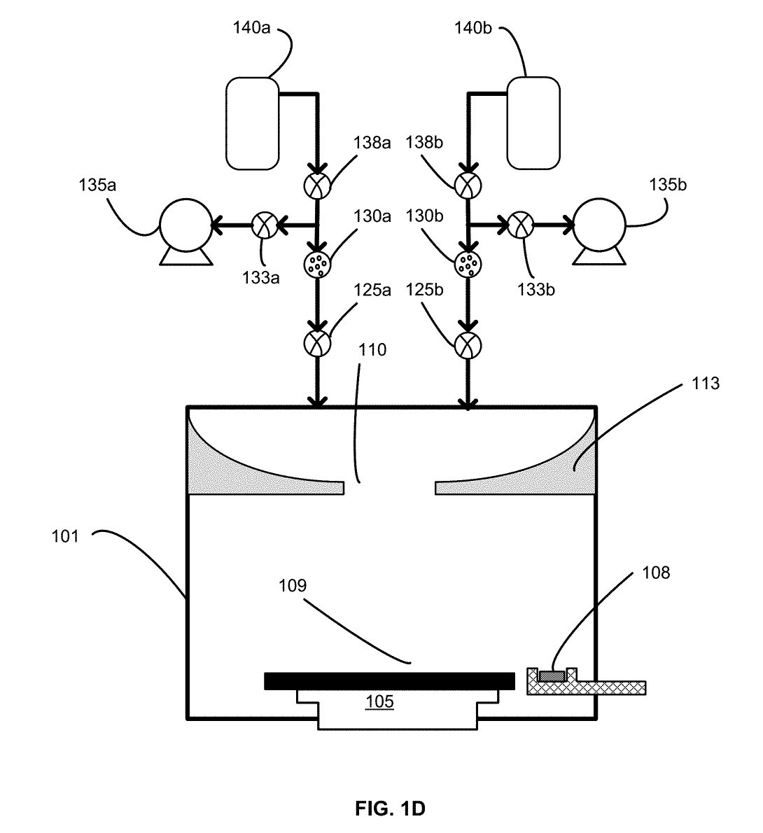

FIG. 1A shows a system for atomic layer etching or deposition according to embodiments. Any or all aspects of the embodiments depicted in each of FIGS. 1A, 1B, 1C, 1D may be combined to form other embodiments. A first precursor source 140a delivers a first precursor through upstream source valve 138a and downstream source valve 125a and chamber entry valve 115a during a first portion of an atomic layer process such as atomic layer deposition or atomic layer etching. Specific examples of suitable precursors will be described following the description of the hardware. The first precursor flows into remote region 112, through a showerhead 111 and then into substrate processing region 110 to chemically react with substrate 109 in the first half-reaction. The substrate is supported on the substrate pedestal 105 during all the chemical reactions described herein. There are regions of substrate 109 which are not visible from the point where the first precursor enters substrate processing chamber 101. In other words, portions of substrate 109 are not within line-of-sight of the entry point of the first precursor into substrate processing chamber 101 as a consequence of a precursor distributor (e.g. showerhead 111) and the process still deposits or etches a monolayer during each full cycle.

During exposure to the first precursor, first source valve 138a and downstream source valve 125a are in the open position. Chamber entry valve 115a is also open to allow the first precursor to enter substrate processing chamber 101 through the entry point. Dump valve 133a may be closed while exposing substrate 109 to the first precursor. Purge gas valve 122a may be closed or open, in embodiments, since the process may tolerate an inert gas which does not affect the chemical reactions taking place on substrate 109.

Downstream source valve 125a may be shut and dump valve 133a may be opened to temporarily redirect first precursor into pump 135a while purging substrate processing chamber and exposing substrate 109 to the second precursor as described shortly. Upstream source valve 138a may be closed after a delay for removing some remaining portion of the first precursor from the deadleg portion of the gas handling system. A purge gas is flowed from purge gas source 123a into substrate processing chamber 101 by opening purge gas valve 122a, setting mass flow controller 118a to a desired flowrate and opening or keeping open chamber entry valve 115a. The purge gas flows into and purges the remote region 112 and the substrate processing region 110.

During the exposure to the first precursor and the purging of substrate processing chamber 101, upstream source valve 138b and dump valve 133b may be open, downstream source valve 125b, chamber entry valve 115b and purge gas valve 122b may all be closed in embodiments. Purge gas valve 122a and/or chamber entry valve 115a may be closed to stop the purge gas from entering substrate processing chamber 101 once the chamber has been purged of the first precursor. Dump valve 133b may be closed, upstream source valve 138b may be opened and chamber entry valve 115b may be opened to flow the second precursor from the second precursor source 140b into substrate processing chamber 101. The second precursor flows into remote region 112, through showerhead 111 and then into substrate processing region 110 to chemically react with substrate 109 in the second half-reaction. The substrate is supported on substrate pedestal 105. In FIG. 1A, the entry point of the first precursor and the second precursor is the same though they are not exposed to substrate 109 simultaneously. Thus, the same portions of substrate 109 which were not within line-of-sight of the entry point of the first precursor are again not within line-of-sight of the entry point of the second precursor. The combination of the first half reaction involving exposure to the first precursor and the second half reaction involving exposure to the second precursor results in deposition or etching of a monolayer.

Downstream source valve 125a was already closed during the purging step and the exposure of substrate 109 to the second precursor. Once the desired exposure to the second precursor has been achieved, downstream source valve 125b may be closed and dump valve 133b may be opened to redirect the second precursor into pump 135b temporarily while purging substrate processing chamber and exposing substrate 109 to the first precursor as described previously or preparing to transfer substrate 109 out of substrate processing chamber 101. In embodiments, upstream source valve 138b may be closed or left open to keep a steady flow especially useful if precursor source 140b is a bubbler. Bubbler technology may result in an undesirable irregularity in initial flow rate if the flow of carrier gas in entirely interrupted. A purge gas is flowed from purge gas source 123b into substrate processing chamber 101 by opening purge gas valve 122b, setting mass flow controller 118b to a desired flowrate and opening or keeping open chamber entry valve 115b. The purge gas flows into and purges the remote region 112 and the substrate processing region 110.

FIG. 1B shows a system for atomic layer etching or deposition according to embodiments. Some features were left out of FIG. 1A primarily to make the drawing more understandable. as such, aspects of each of FIGS. 1A, 1B, 1C and 1D may be combined to form other embodiments. A first precursor source 140a delivers a first precursor through upstream source valve 138a, source filter 130a, downstream source valve 125a and chamber entry valve 115a during a first portion of an atomic layer process such as atomic layer deposition or atomic layer etching. The first precursor flows into remote region 112, contacts a baffle 113 either directly or indirectly, and then flows into substrate processing region 110 to chemically react with substrate 109 in the first half-reaction. Portions of substrate 109 are not within line-of-sight of the first entry point of the first precursor into substrate processing chamber 101 as a consequence of a precursor distributor (e.g. baffle 113) and the process still deposits or etches a monolayer during each full cycle since all reactions described herein are driven by substrate temperature.

During exposure to the first precursor, upstream source valve 138a and downstream source valve 125a are in the open position. Chamber entry valve 115a is also open to allow the first precursor to enter substrate processing chamber 101 through the first entry point. Dump valve 133a may be closed while exposing substrate 109 to the first precursor. Purge gas valve 122a may be closed or open, in embodiments, since the process may tolerate an inert gas which does not affect the chemical reactions taking place on substrate 109.

Following exposure to the first precursor, downstream source valve 125a may be shut and dump valve 133a may be opened to temporarily redirect first precursor into pump 135a until it is time to expose substrate 109 to the first precursor again. Upstream source valve 138a may be closed after a delay to allow for removal of some remaining portion of the first precursor from the deadleg portion of the gas handling system. A purge gas is flowed from purge gas source 123a into substrate processing chamber 101 by way of purge filter 121a to improve particle performance of the monolayer-per-cycle etching or deposition. the purge gas may be flowed by setting mass flow controller 118a to a desired flowrate and opening or keeping open chamber entry valve 115a. The purge gas flows into and purges substrate processing region 110.

During the exposure to the first precursor and the purging of substrate processing chamber 101, upstream source valve 138b and dump valve 133b may be open, downstream source valve 125b and chamber entry valve 115b may be closed in embodiments. Chamber entry valve 115a may be closed to stop the purge gas from entering substrate processing chamber 101 once the chamber has been purged of the first precursor. Dump valve 133b may be closed, upstream source valve 138b may be opened and chamber entry valve 115b may be opened (if not open already) to flow the second precursor from the second precursor source 140b through source filter 130b into substrate processing chamber 101. The second precursor flows into substrate processing chamber 101 through a second entry point. The second precursor has its flow redistributed by baffle 113 and then chemically reacts with substrate 109 in the second half-reaction. In FIG. 1B, the entry point of the first precursor (the first entry point) and the second precursor (the second entry point) are at different points on the substrate processing chamber. As a consequence, different portions of substrate 109 may not be within line-of-sight of the first entry point compared to those portions not within line-of-sight of the second entry point of the second precursor. The combination of the first half reaction involving exposure to the first precursor and the second half reaction involving exposure to the second precursor results in deposition or etching of a monolayer.

Downstream source valve 125a was already closed during the purging step and the exposure of substrate 109 to the second precursor. Once the desired exposure to the second precursor has been achieved, downstream source valve 125b may be closed and dump valve 133b may be opened to redirect second precursor into pump 135b temporarily while purging substrate processing chamber and exposing substrate 109 to the first precursor as described previously or preparing to transfer substrate 109 out of substrate processing chamber 101. Upstream source valve 138b may be closed or left open according to embodiments. A purge gas is flowed from purge gas source 123b, through purge filter 121b, into substrate processing chamber 101 by setting mass flow controller 118b to a desired flowrate and opening or keeping open chamber entry valve 115b. The purge gas flows into and purges the substrate processing region 110.

FIG. 1C shows a system for atomic layer etching or deposition according to embodiments. Some features were left out of FIG. 1C but were already described in the discussion associated with FIGS. 1A and 1B. Removing some details allows FIG. 1C to show alternative embodiments and additional details. A first precursor source 140a delivers a first precursor through upstream source valve 138a, source filter 130a, and downstream source valve 125a during a first portion of an atomic layer process such as atomic layer deposition or atomic layer etching. The first precursor flows into remote region 112, contacts a baffle 113 either directly or indirectly, and then flows into substrate processing region 110 to chemically react with substrate 109 in the first half-reaction. Portions of substrate 109 are not within line-of-sight of the first entry point of the first precursor into substrate processing chamber 101 as a consequence of a precursor distributor (e.g. baffle 113) and the process still deposits or etches a monolayer during each full cycle since all reactions described herein are driven by substrate temperature.

During exposure to the first precursor, upstream source valve 138a and downstream source valve 125a are open to allow the first precursor to enter substrate processing chamber 101 through the first entry point. Dump valve 133a may be closed while exposing substrate 109 to the first precursor. Hardware used to purge the substrate processing region is not included FIG. 1C or 1D. Purging hardware may be included or not included in embodiments.

During the exposure to the first precursor and any purging of substrate processing chamber 101, upstream source valve 138b and dump valve 133b may be open, meanwhile, downstream source valve 125b may be closed in embodiments. Prior to exposing substrate 109 to the second precursor, dump valve 133b may be closed, upstream source valve 138b may be opened. Downstream source valve 125b may be opened to flow the second precursor from the second precursor source 140b through source filter 130b into substrate processing chamber 101. The second precursor flows into substrate processing chamber 101 through a second entry point. The second precursor has its flow redistributed by baffle 113 and then the second precursor chemically reacts with substrate 109 in the second half-reaction. In FIG. 1C, the entry point of the first precursor (the first entry point) and the second precursor (the second entry point) are at different points on the substrate processing chamber. As a consequence, different portions of substrate 109 may not be within line-of-sight of the first entry point compared to those portions not within line-of-sight of the second entry point of the second precursor. The combination of the first half reaction involving exposure to the first precursor and the second half reaction involving exposure to the second precursor results in deposition or etching of a monolayer.

Downstream source valve 125a was already closed during the purging step and the exposure of substrate 109 to the second precursor. Once the desired exposure to the second precursor has been achieved, downstream source valve 125b may be closed and dump valve 133b may be opened to redirect second precursor into pump 135b temporarily while purging substrate processing chamber and exposing substrate 109 to the first precursor as described previously or preparing to transfer substrate 109 out of substrate processing chamber 101. Upstream source valve 138b may open or closed in embodiments. A purge gas may or may not be flowed into substrate processing chamber 101 to clean substrate processing region 110 prior to additional half reactions or removal of substrate 109 from substrate processing region 110.

A quartz crystal microbalance (QCM) 108 is included within substrate processing region 110 disposed in close proximity to substrate 109 so an accurate measurement may be made of the material lost or gained during the etching or deposition processes described herein. Quartz crystal microbalance 108 may be within 20%, within 10% or within 5% of the major lateral dimension of the substrate (e.g. the diameter), according to embodiments, of the closest point on substrate 109. Quartz crystal microbalance 108 may be disposed between substrate 109 and baffle 113, between substrate 109 and the first entry point, between substrate 109 and the second entry point, in embodiments. The hardware and processes described herein tolerate a lack of line-of-sight access from the first entry point and the second entry point which enables quartz crystal microbalance to be positioned above substrate 109 without interfering with the deposition or the etching processes.

FIG. 1D shows a system for atomic layer etching or deposition according to embodiments. In this case, the quartz crystal microbalance 108 is included within substrate processing region 110 but disposed such that the sensing surface is approximately coplanar or coplanar with the top of substrate 109. Positioning quartz crystal microbalance 108 at the same plane of substrate 109, in embodiments, may increase the accuracy of the measurement in some instances.

Precursor source 140a and precursor source 140b may be bubblers. In bubblers, a carrier gas is flowed through a liquid or solid precursor source to pick up the precursor from the vapor pressure. The liquid or solid precursor is generally heated during operation to increase the vapor pressure. Purge filter 121a, purge filter 121b, source filter 130a and source filter 130b may only be selected to allow passage for particles smaller than 30 nm, smaller than 20 nm, smaller than 15 nm, smaller than 10 nm, smaller than 7 nm, smaller than 5 nm or smaller than 3 nm according to embodiments.

All systems described herein may be controlled by a system controller comprising one or more computers, human interface devices for maintaining and programming process recipes. The system controller may be electrically connected to any or all the valves, mass flow controllers and substrate processing chamber to open/close valves, set flow rates and operate substrate handling robots for example. A storage drive may be included in the system controller for storing instructions of the recipes described herein. Pump 135a and pump 135b may be a high vacuum or low vacuum pump such as a rotary vane pump or a roots pump which can handle the flow rates typically coming from a precursor source.

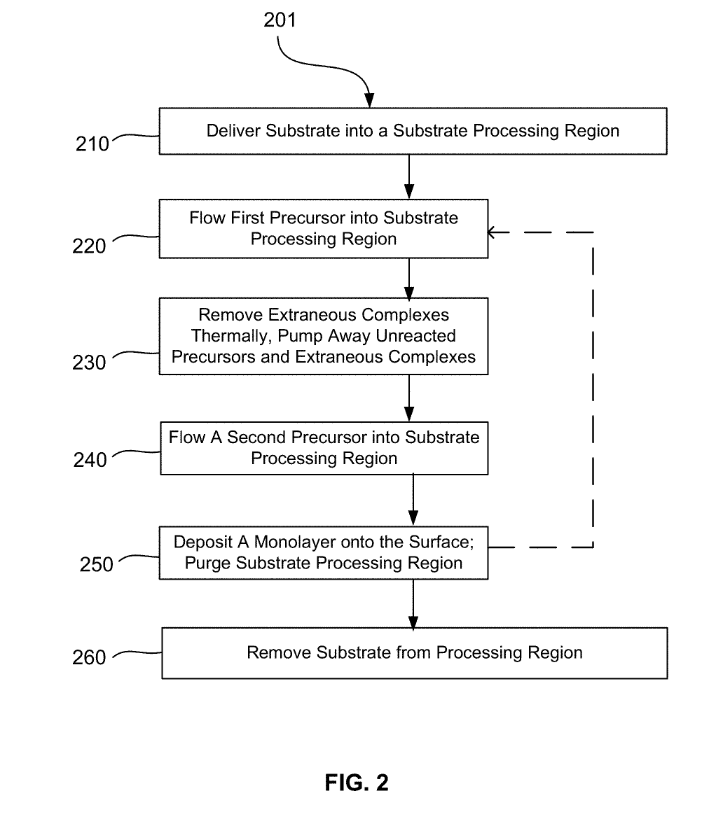

FIG. 2 is a flow chart of an atomic layer deposition process according to embodiments. A method of depositing material onto a surface of a patterned substrate in a substrate processing region of a substrate processing chamber 201 begins when a patterned substrate is placed in the substrate processing region 210. A first precursor is flowed into the substrate processing region through a first entry point into the substrate processing chamber in operation 220. There is no direct line-of-sight path between a portion of the substrate and the entry point of the first precursor into the substrate processing chamber. The adsorption chemical reaction may proceed without any plasma excitation to the first precursor. The adsorption does not require a neutral or ionic beam excitation in embodiments. The flow of the first precursor into the substrate processing region is stopped. Extraneous chemical complexes are desorbed thermally from the substrate and the extraneous chemical complexes and any unreacted first precursor are removed from the substrate processing region through a pump (operation 230).

A second precursor is then flowed into the substrate processing region through a second entry point into the substrate processing chamber in operation 240. As with the first precursor, there is no direct line-of-sight path between a portion of the substrate and the entry point of the second precursor into the substrate processing chamber. The adsorption chemical reaction may proceed without any plasma excitation to the second precursor. The adsorption does not require a neutral or ionic beam excitation in embodiments. The flow of the second precursor into the substrate processing region is stopped. Any extraneous chemical complexes are desorbed thermally from the substrate and the extraneous chemical complexes and any unreacted second precursor are removed from the substrate processing region through a pump (operation 250). A monolayer of material is added to the patterned substrate (also operation 250). Operations 220-250 may be repeated to deposit another monolayer or any integral number of monolayers in embodiments.

To perform purely thermal ALD as described herein, the first precursor may be a metal precursor. The second precursor may be an oxygen-containing precursor, a nitrogen-containing precursor or a sulfur-containing precursor in embodiments. The deposited material may be a metal oxide such as aluminum oxide (e.g. Al₂O₃) or titanium oxide (e.g. TiO₂) in embodiments. The deposited material may be a metal nitride such as titanium nitride (e.g. TiN), tantalum nitride (e.g. TaN) or tungsten nitride (e.g. W₂N) according to embodiments. The deposited material may be a metal sulfide such as zinc sulfide (e.g. ZnS) or cadmium sulfide (e.g. CdS) in embodiments. The oxygen-containing precursor may be one or a combination of H₂O, H₂O₂, O₂ or O₃ in embodiments. The oxygen-containing precursor may consist of oxygen or consist of oxygen and hydrogen according to embodiments. The nitrogen-containing precursor may be one or more of NH₃, N₂H₂, N₂H₄ according to embodiments. The nitrogen-containing precursor may consist of nitrogen and hydrogen in embodiments. The sulfur-containing precursor may be H₂S and may consist of hydrogen and sulfur according to embodiments. The metal-containing precursor may comprise aluminum, titanium, tantalum or tungsten in embodiments. For the purposes of illustration, the metal-containing precursor may be one of [(C₂H₅)₂N]₄Ti, [(CH₃)₂N]₄Ti, [(CH₃C₂H₅)N]₄Ti, Ti[OCC(CH₃)₃CHCOC(CH₃)₃]₂(OC₃H₇)₂, Ti[OCH(CH₃)₂] according to embodiments. The metal-containing precursor may consist of one of the metal elements (Al, Ti, Ta or W), carbon, hydrogen and nitrogen in embodiments. The metal-containing precursor may consist of one of the metal elements (Al, Ti, Ta or W), carbon, hydrogen and oxygen in embodiments.

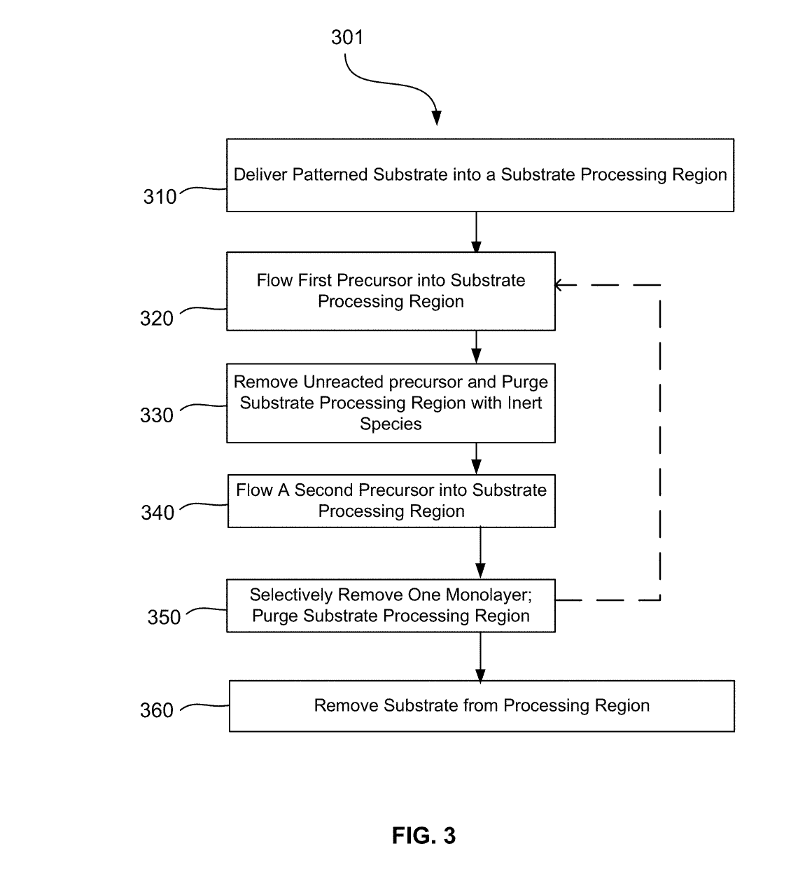

FIG. 3 is a flow chart of an atomic layer etching process according to embodiments. A method of etching material from a surface of a patterned substrate in a substrate processing region of a substrate processing chamber 201 begins when a patterned substrate is placed in the substrate processing region 210. A first precursor is flowed into the substrate processing region through a first entry point into the substrate processing chamber in operation 220. There is no direct line-of-sight path between a portion of the substrate and the entry point of the first precursor into the substrate processing chamber. The adsorption chemical reaction may proceed without any plasma excitation to the first precursor. The adsorption does not require a neutral or ionic beam excitation in embodiments. The flow of the first precursor into the substrate processing region is stopped. Extraneous chemical complexes are desorbed thermally from the substrate and the extraneous chemical complexes and any unreacted first precursor are removed from the substrate processing region through a pump (operation 230).

A second precursor is then flowed into the substrate processing region through a second entry point into the substrate processing chamber in operation 240. As with the first precursor, there is no direct line-of-sight path between a portion of the substrate and the entry point of the second precursor into the substrate processing chamber. The adsorption chemical reaction may proceed without any plasma excitation to the second precursor. The adsorption does not require a neutral or ionic beam excitation in embodiments. The flow of the second precursor into the substrate processing region is stopped. Any extraneous chemical complexes are desorbed thermally from the substrate and the extraneous chemical complexes and any unreacted second precursor are removed from the substrate processing region through a pump (operation 250). A monolayer of material is removed from the patterned substrate (also operation 250). Operations 220-250 may be repeated to etch another monolayer or any integral number of monolayers in embodiments.

To perform purely thermal ALE as described herein, the first precursor may be very electronegative and may be a halogen-containing precursor according to embodiments. The first precursor may comprise one or more of F, Cl, Br or I in embodiments. The first precursor may comprise fluorine in a preferred embodiment. The first precursor may be one or more of HF.pyridine (C₅H₆FN), F₂, HF, NF₃, ClF₃, SF₄, SF₆, XeF₂ according to embodiments. The first precursor may comprise a chemical comprising a lone pair containing species (e.g. CH₃, H₂O, NH₃ or OH) in embodiments. The first precursor may be a complex anionic species (e.g. SOx) according to embodiments. The second precursor may donate a ligand to the metal anion layer to produce volatile metal complex which can be removed thermally without any other source of energy beyond the temperature of the substrate and chemical potential energy in embodiments. The second precursor may be a β-diketonate (e.g. tin acetylacetonate or Sn(acac)₂), a metal alkyl (e.g. trimethyl aluminum or triethyl aluminum), a metal halide (e.g. TiCl₄), an alkoxide (e.g. Al[OCH(CH₃)₂]₃ or Ti[OCH(CH₃)₂]₄) according to embodiments. The second precursor may be a silicon-containing precursor (e.g. SiCl₄). The second precursor may be a metal-containing precursor, in embodiments, such as a metal amide. The second precursor may be a silylamide. The second precursor may comprise one of Ti, Al, Zn or Sn according to embodiments. The second precursor may consist of one of the metal elements (Al, Ti, Zn or Sn), carbon, hydrogen and oxygen in embodiments. The second precursor may consist of one of the metal elements (Al, Ti, Zn or Sn), carbon, hydrogen, nitrogen and oxygen in embodiments. The second precursor may consist of one of the metal elements (Al, Ti, Zn or Sn), carbon, hydrogen, silicon, nitrogen and oxygen in embodiments.

The methods described herein may be used to deposit or remove material at a uniform thickness of between 0.5 nm and 20 nm, between 1 nm and 10 nm or between 2 nm and 5 nm according to embodiments. Higher etch amounts within these ranges may benefit from applying a plurality of cycles of operations 120-150 (or 220-250 in the next example). Each cycle may remove metals and metal nitrides at a uniform thickness of between 0.1 nm and 2 nm or between 0.2 nm and 1 nm according to embodiments. A cycle may be repeated an integral number of times, for example over ten times, over twenty times, over fifty times or over one hundred times according to embodiments. The etch rate at near the bottom of a high aspect ratio feature may be within 12%, within 7%, within 5% or within 3% of the etch rate near the opening of the high aspect ratio feature in embodiments. The depth of a via or trench (high aspect ratio features) may be greater than 0.5 μm, greater than 1.0 μm or greater than 2.0 μm according to embodiments. The width of via or trench (in the narrower dimension) may be less than 30 nm, less than 20 nm or less than 10 nm in embodiments. The depth-to-width aspect ratio may be greater than ten, greater than fifty or greater than one hundred according to embodiments.

The substrate temperatures described next apply to all the embodiments herein. The substrate temperature may be between 30° C. and 800° C., between 200° C. and 600° C., between 200° C. and 450° C., between 250° C. and 500° C., or between 300° C. and 400° C. according to embodiments. These temperatures may apply to operation 130, operation 230, operations 120-130, operations 220-230, operations 120-150 and operations 220-250 in embodiments.

Absence (or reduction in magnitude) of any local plasma, remote plasma or any excitation beyond the thermal influence of the substrate may be present in all embodiments described herein. All local or remote regions may be said to be plasma free. The term “plasma-free” will be used herein to describe the substrate processing region during application of no or essentially no plasma power to the substrate processing region. The precursors described possess energetically favorable etch reaction pathways which enable the substrate processing region to be plasma-free during operations of etching materials as described herein. Stated another way, the electron temperature in the substrate processing region (and independently any remote regions) may be less than 0.5 eV, less than 0.45 eV, less than 0.4 eV, or less than 0.35 eV according to embodiments. Moreover, the precursors may have not been excited in any remote plasma prior to entering the substrate processing region in embodiments. For example, if a remote region or a separate chamber region is present and used to conduct the precursors toward the substrate processing region, the separate chamber region or remote region may be plasma-free as defined herein. Etch processes 101 and 201 may contain at least two repetitions of operations 120-150 or 220-250, respectively, in embodiments.

In all embodiments described herein, the precursors are supplied at a flow rate of between 5 sccm and 500 sccm, between 10 sccm and 300 sccm, between 25 sccm and 200 sccm, between 50 sccm and 150 sccm or between 75 sccm and 125 sccm. Any inert gas carrier gas may be supplied at a flow rate of between 5 sccm and 2,000 sccm, between 10 sccm and 1,000 sccm, between 25 sccm and 700 sccm, between 50 sccm and 500 sccm or between 100 sccm and 300 sccm in any of the embodiments described herein.

The reactions may proceed thermally, excited only by the temperature of the substrate itself, according to embodiments. In embodiments which rely on the temperature of the substrate to effect the etching reaction, the term “plasma-free” may be used herein to describe the substrate processing region during application using no or essentially no plasma power. The plasma power may also be kept below small threshold amounts to enable the appropriate reactions to proceed. The plasma power applied to the substrate processing region may be less than 100 watts, less than 50 watts, less than 30 watts, less than 10 watts and may be 0 watts in embodiments. The process pressures described next apply to all the embodiments herein. The pressure within the substrate processing region may be between 0.1 Torr and 50 Torr, between 0.2 Torr and 30 Torr, between 0.5 Torr and 20 Torr, between 1 Torr and 10 Torr in embodiments.

Each of the embodiments described herein possess purging operations which may occur after the patterned substrate is exposed to the first precursor and after the patterned substrate is exposed to the second precursor. Generally speaking, the etching operations of all processes described herein may instead simply have a stoppage in the flow of precursors into the substrate processing region during the processes disclosed and claimed herein. Alternatively, as in the examples, the substrate processing region may be actively purged using a gas which displays essentially no chemical reactivity to the exposed materials on the patterned substrate. After the precursor stoppage or the active purging, the next precursor may be flowed into the substrate processing region to begin the oxidation or the removal of the oxidation layer from the patterned substrate.

An advantage and benefit of the processes described herein lies in the conformal rate of removal of material from the substrate. The methods involve a conformal deposition operation or a conformal removal operation in embodiments. As used herein, a conformal etch process refers to a generally uniform removal rate of material from a patterned surface regardless of the shape of the surface. analogously, a conformal deposition process refers to a generally uniform removal rate of material from a patterned surface regardless of the shape of the surface. The surface of the layer before and after the etch process are generally parallel. A benefit of the processes and equipment described herein involves a conformal removal or deposition from a surface which has a high surface area and/or possesses large aspect ratio trenches in embodiments. Traditional atomic layer deposition and/or etching involved bombardment of the adsorbed precursors with a neutral or ionic beam of impinging molecules. Those traditional treatments were not able to treat the interior surfaces of high aspect ratio trenches and other features due to shielding effects. A person having ordinary skill in the art will recognize that the etch or deposition process likely cannot be 100% conformal and thus the term “generally” allows for acceptable tolerances. Similarly, a conformal layer refers to a layer having generally uniform thickness. A conformal layer may have an outer surface in the same shape as the inner surface, i.e., the outer surface and the inner surface are generally parallel.

The flow of precursors into the substrate processing region may further include one or more relatively inert gases such as He, N₂, Ar. The inert gas may be included, for example, to improve process uniformity. Process uniformity is generally increased when helium is included. These additives are present in embodiments throughout this specification. Flow rates and ratios of the different gases may be used to control etch rates and etch selectivity.

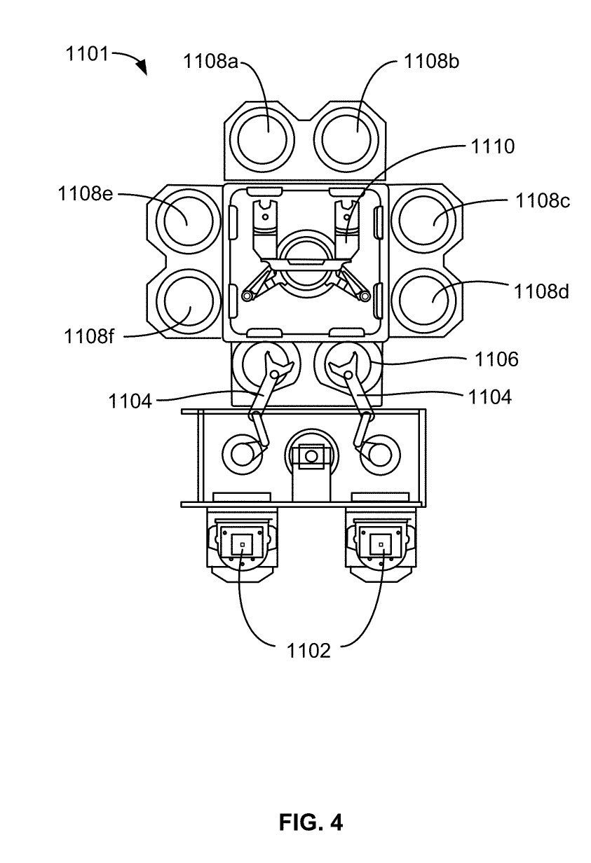

Embodiments of the substrate processing chambers may be incorporated into larger fabrication systems for producing integrated circuit chips. FIG. 4 shows one such processing system (mainframe) 1101 of deposition, etching, baking, and curing chambers in embodiments. In the figure, a pair of front opening unified pods (load lock chambers 1102) supply substrates of a variety of sizes that are received by robotic arms 1104 and placed into a low pressure holding area 1106 before being placed into one of the substrate processing chambers 1108a-f. A second robotic arm 1110 may be used to transport the substrate wafers from the holding area 1106 to the substrate processing chambers 1108a-f and back. Each substrate processing chamber 1108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “metal” of the patterned substrate is predominantly a metal element but may include minority concentrations of other elemental constituents such as nitrogen, oxygen, hydrogen, silicon and carbon. Exposed “metal” may consist of or consist essentially of a metal element. Exposed “metal nitride” of the patterned substrate is predominantly nitrogen and a metal element but may include minority concentrations of other elemental constituents such as oxygen, hydrogen, silicon and carbon. Exposed “metal nitride” may consist of or consist essentially of nitrogen and a metal element. Exposed “silicon” or “polysilicon” of the patterned substrate is predominantly Si but may include minority concentrations of other elemental constituents such as nitrogen, oxygen, hydrogen and carbon. Exposed “silicon” or “polysilicon” may consist of or consist essentially of silicon. Exposed “silicon nitride” of the patterned substrate is predominantly silicon and nitrogen but may include minority concentrations of other elemental constituents such as oxygen, hydrogen and carbon. “Exposed silicon nitride” may consist essentially of or consist of silicon and nitrogen. Exposed “silicon oxide” of the patterned substrate is predominantly SiO₂ but may include minority concentrations of other elemental constituents (e.g. nitrogen, hydrogen, carbon). In some embodiments, silicon oxide regions etched using the methods disclosed herein consist essentially of silicon and oxygen.

The term “precursor” is used to refer to any process gas which takes part in a reaction to either remove material from or deposit material onto a surface. The phrase “inert gas” refers to any gas which does not form chemical bonds when etching or being incorporated into a layer. Exemplary inert gases include noble gases but may include other gases so long as no chemical bonds are formed when (typically) trace amounts are trapped in a layer.

A gap is an etched geometry having any horizontal aspect ratio. Viewed from above the surface, gaps may appear circular, oval, polygonal, rectangular, or a variety of other shapes. A “trench” is a long gap. A trench may be in the shape of a moat around an island of material whose aspect ratio is the length or circumference of the moat divided by the width of the moat. A “via” is a short gap with horizontal aspect ratio, as viewed from above, near unity. A via may appear circular, slightly oval, polygonal or slightly rectangular. A via may or may not be filled with metal to form a vertical electrical connection.

Having disclosed several embodiments, it will be recognized by those of skill in the art that various modifications, alternative constructions, and equivalents may be used without departing from the spirit of the disclosed embodiments. Additionally, a number of well known processes and elements have not been described to avoid unnecessarily obscuring the disclosed embodiments. Accordingly, the above description should not be taken as limiting the scope of the claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the disclosed embodiments, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

1. An substrate processing system, comprising:
a substrate processing chamber containing a substrate processing region;
a first precursor source;
a first upstream source valve fluidly coupled to the first precursor source;
a first dump valve fluidly coupled to the upstream source valve;
a first pump fluidly coupled to the dump valve;
a first downstream source valve fluidly coupled to the first upstream source valve;
a first chamber entry valve fluidly coupled to the first downstream source valve and to the substrate processing chamber at a first entry point;
a second precursor source;
a second upstream source valve fluidly coupled to the second precursor source;
a second dump valve fluidly coupled to the upstream source valve;
a second pump fluidly coupled to the dump valve;
a second downstream source valve fluidly coupled to the second upstream source valve;
a second chamber entry valve fluidly coupled to the second downstream source valve and to the substrate processing chamber at a second entry point;
a precursor distributor disposed within the substrate processing chamber; and
a substrate pedestal configured to support a substrate, wherein there are portions of the substrate which are physically shielded by the precursor distributor from a direct line-of-sight path from the first entry point and the second entry point.

2. The substrate processing system of claim 1 wherein the first precursor source is a bubbler.

3. The substrate processing system of claim 1 wherein the first entry point is the same as the second entry point.

4. The substrate processing system of claim 1 further comprising a first supply filter fluidly coupled between the first upstream source valve and the first downstream source valve.

5. The substrate processing system of claim 1 further comprising:
a first purge gas source;
a first purge gas valve fluidly coupled between the first purge gas source and the first chamber entry valve.

6. The substrate processing system of claim 5 further comprising a first mass flow controller fluidly coupled between the first purge gas valve and the first chamber entry valve.

7. The substrate processing system of claim 1 wherein the precursor distributor is a showerhead separating a remote region from the substrate processing region.

8. The substrate processing system of claim 1 wherein the precursor distributor is baffle.

9. The substrate processing system of claim 1 further comprising a quartz crystal microbalance disposed within the substrate processing region.

10. The substrate processing system of claim 9 wherein the quartz crystal microbalance is disposed between the substrate and the first entry point.

11. The substrate processing system of claim 9 wherein the quartz crystal microbalance is disposed next to the substrate such that the quartz crystal microbalance and the substrate are coplanar.

12. A method of depositing material onto a surface of a patterned substrate in a substrate processing region of a substrate processing chamber, the method comprising
at least four sequential steps (“a deposition cycle”) comprising:
(i) exposing the patterned substrate to a first precursor into the substrate processing region through a first entry point on the substrate processing chamber,
(ii) removing process effluents including unreacted first precursor from the substrate processing region,
(iii) exposing the patterned substrate to a second precursor into the substrate processing region through a second entry point on the substrate processing chamber, and
(iv) removing process effluents including unreacted second precursor from the substrate processing region; and
wherein no direct line-of-sight path exists between a portion of the substrate and the entry point of the first precursor into the substrate processing chamber.

13. The substrate processing system of claim 12 wherein the deposition cycle is repeated an integral number of times and each deposition cycle deposits a monolayer of material onto the surface of the patterned substrate.

14. The substrate processing system of claim 12 wherein the patterned substrate comprises patterned features which shield portions of the surface of the patterned substrate from a direct line-of-sight path to the second entry point.

15. A method of etching material from a surface of a patterned substrate in a substrate processing region of a substrate processing chamber, the method comprising
at least four sequential steps comprising an etch cycle:
(i) exposing the patterned substrate to a first precursor into the substrate processing region through a first entry point on the substrate processing chamber,
(ii) removing process effluents including unreacted first precursor from the substrate processing region,
(iii) exposing the patterned substrate to a second precursor into the substrate processing region through a second entry point on the substrate processing chamber, and
(iv) removing process effluents including unreacted second precursor from the substrate processing region; and
wherein no direct line-of-sight path exists between a portion of the substrate and the entry point of the first precursor into the substrate processing chamber.

16. The substrate processing system of claim 15 wherein the etch cycle is repeated an integral number of times and each etch cycle removes a monolayer of material from the surface of the patterned substrate.

17. The substrate processing system of claim 15 wherein the patterned substrate comprises patterned features which shield portions of the surface of the patterned substrate from a direct line-of-sight path to the first entry point.
